(19) United States
(12) Patent Application Publication
(10) Pub. No.: US 2009/0015259 A1
(43) Pub. Date: Jan. 15, 2009

(54) SYSTEMS AND METHODS FOR MOUNTING INSTRUMENTS ON NMR SYSTEMS

(76) Inventor: Alistair G. Courtney, Oxford (GB)

Correspondence Address: Varian Inc.;Legal Department, 3120 Hansen Way D-102, Palo Alto, CA, 94304, US

(21) Appl. No.: 12/147,945

(22) Filed: Jun. 27, 2008

(30) Foreign Application Priority Data
Jul. 13, 2007 (EP) 07013757.5

(51) Int. Cl. G01R 33/32

(52) U.S. Cl. 324/318

(57) ABSTRACT

According to one aspect, a suspended mounting bridge is used to attach a nuclear magnetic resonance (NMR) instrument assembly including shim coils and/or an NMR probe to an NMR magnet cryostat. The mounting bridge is suspended across a central region of an end cover (e.g. bottom plate) of the cryostat. Consequently, flexing of the end cover center in response to changes in environmental pressure does not cause displacement of the shim coils and/or RF coils relative to the NMR magnet center. The mounting bridge may be attached to a peripheral region of the end cover (e.g. along its perimeter), and/or to a cryostat side wall. The mounting bridge may be shaped as a quasi-rectangular strip or may include multiple spokes.

### CROSS REFERENCE TO RELATED APPLICATIONS

The subject patent application is claiming priority of European Patent Application No. 07013757.5 filed in the European Patent Office on Jul. 13, 2007.

### FIELD OF THE INVENTION

The invention in general relates to nuclear magnetic resonance (NMR) spectroscopy, and in particular to NMR magnets and associated systems and methods for mounting NMR components such as shim coils to NMR magnets.

### BACKGROUND OF THE INVENTION

Nuclear magnetic resonance (NMR) spectrometers typically include a superconducting magnet for generating a static magnetic field B₀, and an NMR probe including one or more special-purpose radio-frequency (RF) coils for generating a time-varying magnetic field B₁ perpendicular to the field B₀, and for detecting the response of a sample to the applied magnetic fields. Each RF coil and associated circuitry can resonate at the Larmor frequency of a nucleus of interest present in the sample. The RF coils are typically provided as part of an NMR probe, and are used to analyze samples situated in sample tubes or flow cells. The direction of the static magnetic field B₀ is commonly denoted as the z-axis or longitudinal direction, while the plane perpendicular to the z-axis is commonly termed the x-y or transverse direction.

Generating high-resolution NMR spectra is facilitated by employing a temporally and spatially-homogeneous static magnetic field. The strength of the static magnetic field can vary over time due to temperature fluctuations or movement of neighboring metallic objects, among others. Spatial variations in the static magnetic field can be created by variations in sample tube or sample properties, the presence of neighboring materials, or by the magnet's design. Minor spatial inhomogeneities in the static magnetic field are ordinarily corrected using a set of shim coils, which generate a small magnetic field which opposes and cancels inhomogeneities in the applied static magnetic field.

### SUMMARY OF THE INVENTION

According to one aspect, a nuclear magnetic resonance spectrometer comprises a nuclear magnetic resonance magnet vessel having an end cover and a side wall extending longitudinally from the end cover, the vessel including a longitudinal central bore extending through the end cover; a nuclear magnetic resonance instrument mounting bridge suspended across a central region of the end cover; and a nuclear magnetic resonance instrument assembly attached to a central region of the mounting bridge and positioned within the central bore of the vessel, the instrument assembly including a nuclear magnetic resonance coil.

According to another aspect, a method comprises suspending a nuclear magnetic resonance instrument mounting bridge across a central region of an end cover of a nuclear magnetic resonance magnet vessel, the vessel including a longitudinal central bore extending through the end cover; and attaching a nuclear magnetic resonance instrument assembly to a central region of the mounting bridge to position the nuclear magnetic instrument assembly within the central bore, the instrument assembly including a nuclear magnetic resonance coil.

According to some embodiments, the exemplary NMR instrument mounting systems and methods described below allow keeping the system shim coils and/or RF coils in a fixed position relative to the magnet center by decoupling the coils from any flexing of a central region of the cryostat end cover (e.g. bottom plate) that may occur in response to environmental pressure variations.

### BRIEF DESCRIPTION OF THE DRAWINGS

The foregoing aspects and advantages of the present invention will become better understood upon reading the following detailed description and upon reference to the drawings where:

FIG. 1 is a schematic diagram of an exemplary NMR spectrometer according to some embodiments of the present invention.

FIG. 2 shows an isometric view of an NMR magnet cryostat and associated probe/shim coil mounting bridge according to some embodiments of the present invention.

FIG. 3 shows an isometric view of an NMR magnet cryostat and associated probe/shim coil mounting bridge according to some embodiments of the present invention.

FIG. 4 illustrates several system dimensions and other parameters according to some embodiments of the present invention.

FIG. 5-A shows a mounting bridge attached to the side wall of an NMR magnet cryostat, according to some embodiments of the present invention.

FIG. 5-B shows an NMR magnet cryostat having a domed end cover, according to some embodiments of the present invention.

### DETAILED DESCRIPTION OF THE INVENTION

In the following description, a set of elements includes one or more elements. Any reference to an element is understood to encompass one or more elements. Each recited element or structure can be formed by or be part of a monolithic structure, or be formed from multiple distinct structures. For example, a magnet vessel comprising an end cover and a longitudinal side wall may include an end cover fastened to the side wall, or a monolithic piece including an end cover integrally formed with a side wall. The statement that a mounting bridge is suspended over an end cover is not limited to orientations relative to the direction of gravity, and encompasses a mounting bridge positioned over or under the end cover relative to the direction of gravity. Unless otherwise specified, the term quasi-rectangular encompasses both perfectly rectangular shapes and quasi-rectangular shapes having rounded or otherwise non-linear sides. Unless otherwise specified, a magnet vessel end cover is not limited to structures situated at the top of a magnet vessel, but may include bottom or side plates, domes or other cover structures. Unless otherwise specified, a longitudinal central bore is not necessarily a central bore co-centered with a magnet vessel end cover; a longitudinal central bore may be an off-center longitudinal bore extending through a central region of the end cover.

The following description illustrates embodiments of the invention by way of example and not necessarily by way of limitation.

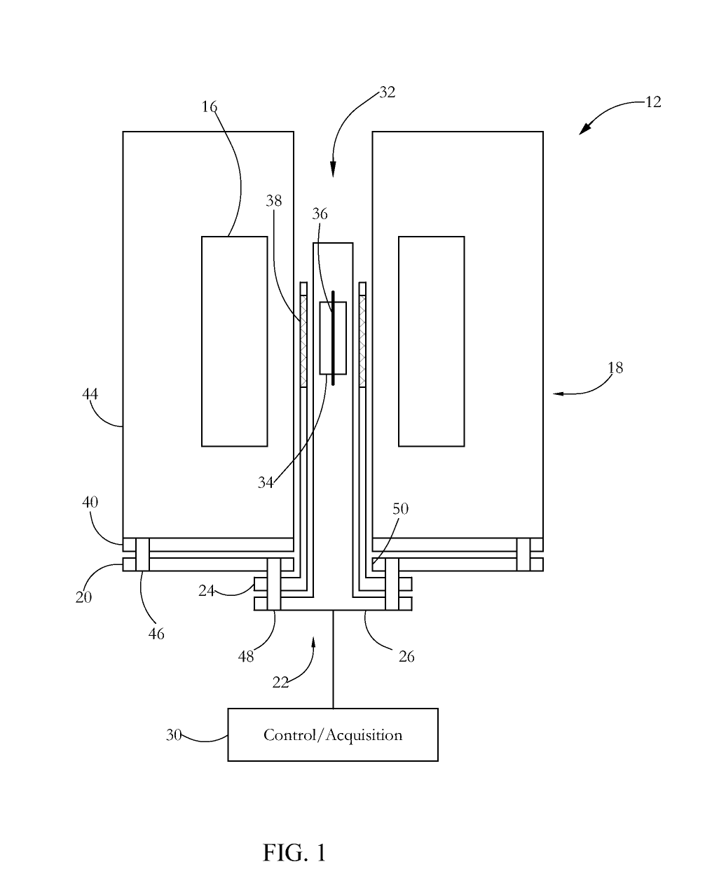

FIG. 1 is a schematic diagram illustrating an exemplary nuclear magnetic resonance (NMR) spectrometer 12 according to some embodiments of the present invention. Spectrometer 12 comprises a magnet 16 held within a vacuum vessel (cryostat) 18, a rigid mounting bridge 20 attached to vessel 18, an instrument assembly 22 including a shim coil assembly 24 and an NMR probe 26 attached to mounting bridge 20, and a control/acquisition system (console) 30 electrically connected to instrument assembly 22. Instrument assembly 22 is positioned in a cylindrical central bore 32 defined through vessel 18.

Probe 26 includes one or more radio-frequency (RF) coils 34 and associated electrical circuit components. A sample container 36 is positioned within probe 26, for holding an NMR sample of interest within coils 34 while measurements are performed on the sample. Sample container 36 can be a sample tube or a flow cell. A set of shim coils 38 laterally enclose RF coils 34.

Vessel 18 may be a metallic cryostat having an external wall and one or more layered, vacuum-isolated internal walls accommodating cryogenic fluid(s) such as liquid nitrogen and/or liquid helium, for keeping the conductors of magnet 16 in a superconducting state. Magnet 16 is suspended in a fixed position within an internal chamber of vessel 18. Vessel 18 includes an end cover 40 and a cylindrical side wall 44. End cover 40 may be a flat (substantially planar) disk-shaped plate, for example a cryostat bottom plate. Side wall 44 extends longitudinally away from end cover 40 and is connected to end cover 40 along a perimeter of end cover 40. End cover 40 is subject to a pressure difference: the pressure on the outer side of end cover 40 is generally atmospheric pressure, while the pressure on the inner side of end cover 40 is a significantly lower vacuum pressure. Mounting bridge 20 is rigidly attached to end cover 40 by a set of fasteners 46 situated along the perimeter of end cover 40, away from central bore 32. Mounting bridge 20 forms a bridge suspended between opposite sides of end cover 40, and extending over central bore 32. Shim coil assembly 24 and NMR probe 26 are rigidly attached to mounting bridge 20 by a set of fasteners 48 situated along a central region of mounting bridge 20. Fasteners 46, 48 may be bolts or other fasteners. Mounting bridge 20 includes a central circular aperture 50 aligned with central bore 32. Shim coil assembly 24 and NMR probe 26 pass through aperture 50 when shim coil assembly 24 and NMR probe 26 are secured within magnet 16.

To perform a measurement, a sample is inserted into a measurement space defined within coils 34. Magnet 16 applies a static magnetic field B₀ to the sample held within sample container 36. Shim coils 38 are used to correct spatial inhomogeneities in the static magnetic field B₀. Control/acquisition system 30 comprises electronic components configured to apply desired radio-frequency pulses to probe 26, and to acquire data indicative of the nuclear magnetic resonance properties of the samples within probe 26. Coils 34 are used to apply radio-frequency magnetic fields B₁ to the sample, and/or to measure the response of the sample to the applied magnetic fields. The RF magnetic fields are perpendicular to the static magnetic field.

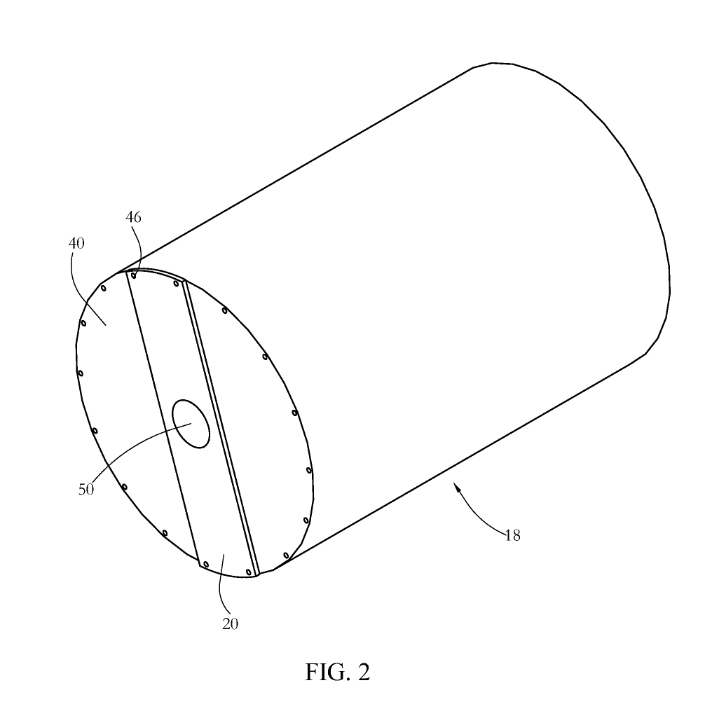

FIG. 2 shows an isometric view of vessel 18 and mounting bridge 20 according to some embodiments of the present invention. Mounting bridge 20 is formed by a quasi-rectangular central strip suspended at opposite ends between opposite sides of end cover 40. Mounting bridge 20 is attached to end cover 40 through fasteners 46 situated at opposite ends of mounting bridge 20, along the perimeter of end cover 40. Mounting bridge 20 is not attached to end cover 40 along a central region Central aperture 50 accommodates NMR instruments inserted through the central bore of vessel 18.

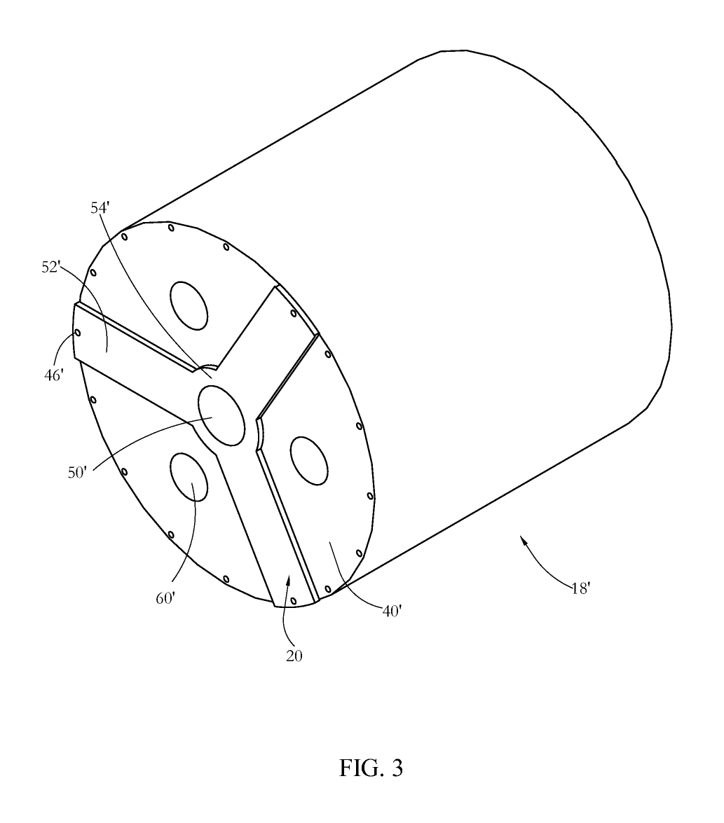

FIG. 3 shows an isometric view of a NMR magnet vessel 18′ and associated probe/shim coil mounting bridge 20′ according to some embodiments of the present invention. Mounting bridge 20′ includes three radial arms 52′ extending between a central annular region 54′ and a perimeter of an end cover 40′ of vessel 18′. Mounting bridge 20′ is secured to end cover 40′ by fasteners 46′ situated at the distal ends of arms 52′, and is not secured to end cover 40′ along annular region 54′. A central aperture 50′ defined in annular region 54′ accommodates NMR instruments inserted through a central bore of vessel 18′. Vessel 18′ includes three apertures 60′, which may be used for transport fixtures and/or a pressure relief safety valve. Transport fixtures may be used to secure vessel 18′ during transport. The mounting bridge design of FIG. 3 may be more costly to fabricate than the rectangular-cover design of FIG. 2. At the same time, the mounting bridge design of FIG. 3 may allow improved access to apertures 60′. A rectangular-cover design such as the one shown FIG. 2 may obstruct access to apertures 60′ if the mounting bridge is sufficiently wide relative to the spacings between apertures 60′.

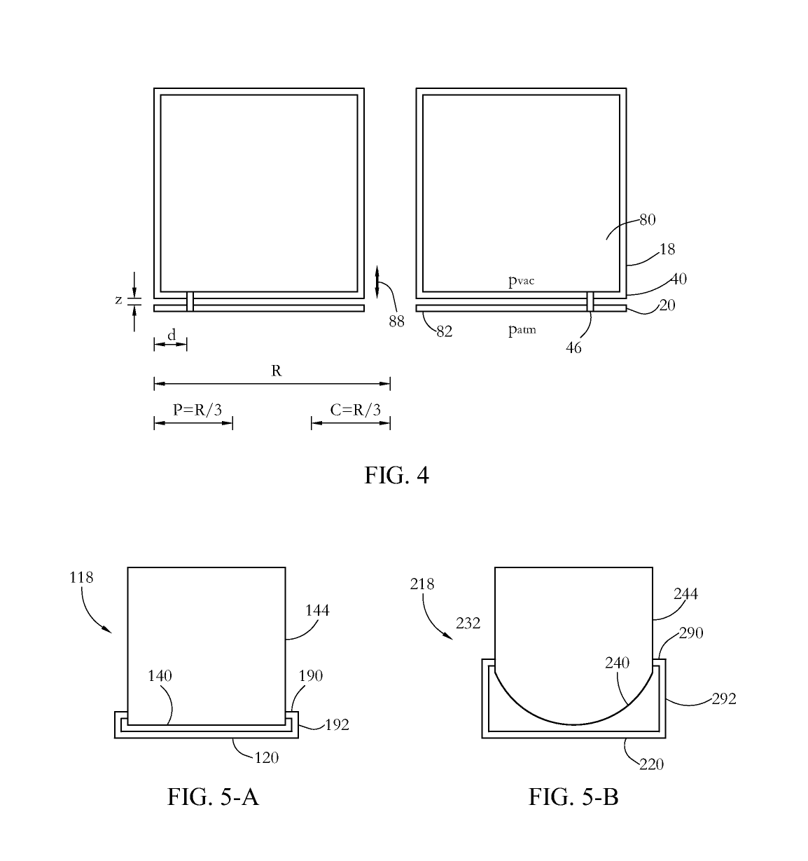

FIG. 4 illustrates several system dimensions and other parameters according to some embodiments of the present invention. The end cover size R denotes the radius of end cover 40 (or more generally, half the transverse extent of end cover 40), while a connection distance d denotes the distance between the outer edge of end cover 40 and the inner-most attachment point(s) of mounting bridge 20 to end cover 40. An inner chamber 80 formed on the inner side of end cover 40 has an internal vacuum pressure p_{vac}, while the outside of end cover 40 is at an atmospheric pressure pₐₜₘ. Both sides (top and bottom) of mounting bridge 20 are at atmospheric pressure. The connection distance d is preferably chosen so that a central part 82 of mounting bridge 20 is decoupled from any longitudinal flexing of the central part of end cover 40 resulting from variations in the pressure difference across end cover 40. Central part 82 serves as an attachment region for attaching NMR instruments to mounting bridge 20. The longitudinal flexing of end cover 40 is schematically illustrated in FIG. 4 by arrow 88. A longitudinal separation z between end cover 40 and mounting bridge 20 is chosen to be sufficient so that end cover 40 does not touch mounting bridge 20 as end cover 40 flexes longitudinally in response to environmental pressure changes.

A peripheral region of end cover 40 and mounting bridge 20 may be defined by a radial extent P=R/3 from the perimeter of end cover 40, while a central region of end cover 40 and mounting bridge may be defined by a radial extent C=R/3 from the center of end cover 40 and mounting bridge 20. Preferably, the innermost point of attachment between mounting bridge 20 and end cover 40 is within the peripheral region, and mounting bridge 20 is suspended over the central region of end cover 40 and is substantially decoupled from any longitudinal motion of the central region of end cover 40.

In some embodiments, the connection distance d is chosen to be as small as mechanically feasible, and fasteners 46 are situated substantially along the perimeter of end cover 40. In some embodiments, the connection distance may be chosen to be much smaller than R, for example less than R/3, or preferably less than R/10. In exemplary embodiments, the end cover radius R may be on the order of tens of cm to 1 m, while the connection distance d may be on the order of several mm or cm. The longitudinal separation z may be on the order of a mm or less.

FIG. 5-A shows a mounting bridge 120 attached to a side wall 144 of an NMR magnet vessel 118. Mounting bridge 120 is attached to side wall 144 along the perimeter of a planar end cover 140. Radial and longitudinal extensions 190, 192 connect mounting bridge 120 to side wall 144. Extensions 190, 192 may be formed by a set of arms or continuous disk-shaped or cylinder-shaped plates/shells, respectively.

FIG. 5-B shows a mounting bridge 220 attached to a side wall 244 of an NMR magnet vessel 218. Vessel 218 has a domed end cover 240. Mounting bridge 220 is attached to a side wall 244 of vessel 218 along the perimeter of end cover 240. Radial and longitudinal extensions 290, 292 connect mounting bridge 220 to side wall 244. A longitudinal central bore 230 extends through the center (tip of the dome) of end cover 240.

It was observed that some NMR systems may be subject to shimming difficulties. Optimal shimming generally depends on precise and stable alignment of the shim coils with respect to the center of the magnet. It was observed that in some NMR cryostats, the end cover(s) may act as diaphragms in response to changes in environmental parameters such as atmospheric pressure, causing slight longitudinal deflections in the positions of the shim coils and/or NMR RF coils relative to the magnet center. While such deflections may be generally small, and are believed to be typically substantially smaller than about 1 mm, they may interfere with the operation of NMR instruments, which depend on the precise alignment of the shim and/or RF coils to the magnet center. The end cover deflections may be particularly pronounced in systems having flat end plates.

Using mounting bridges and/or attachment mechanisms as described above allows substantially decoupling the shim coil and/or RF coil positions from any flexing of the cryostat end cover that results from variations in atmospheric pressure, and thus in the pressure differential across the end cover. Attaching the mounting bridge to the cryostat away from the center of the end cover diaphragm allows minimizing the coupling of the mounting bridge to any end cover motion. The exemplary mounting systems and methods described above may be used in conjunction with or instead of other techniques for stabilizing the position of the shim and/or RF coils relative to the magnet center. Such techniques may include using domed or shaped end covers, using stiffer and/or thicker end cover materials, and adding mechanical reinforcement to the end cover.

The above embodiments may be altered in many ways without departing from the scope of the invention. For example, the end cover described above may be a top, bottom, or side cover. Mounting bridge shapes other than the ones shown in FIGS. 2 and 3 may be used. Such shapes may include a single cantilevered arm or multiple arms attached at one or more points to a cryostat top/bottom cover, or a vented circular cover (a false end cover) parallel to the cryostat top/bottom cover and subject to atmospheric pressure on both sides. An NMR instrument assembly may include shim and RF coils commonly attached to a mounting bridge, or separately attached to the mounting bridge. For example, shim coils may be provided outside or within an NMR probe. In some embodiments, the mounting bridge need not be attached directly to the end cover, but may be attached to another rigid structure (e.g. a rigid ring) mounted on the end cover. Similarly, in some embodiments the NMR instrument assemblies need not be mounted directly on the mounting bridge, but generally may be mounted on a flange or other rigid structure attached to the mounting bridge. Accordingly, the scope of the invention should be determined by the following claims and their legal equivalents.

What is claimed is:

1. A nuclear magnetic resonance spectrometer comprising:
a nuclear magnetic resonance magnet vessel having an end cover and a side wall extending longitudinally from the end cover, the vessel including a longitudinal central bore extending through the end cover;
a nuclear magnetic resonance instrument mounting bridge suspended across a central region of the end cover; and
a nuclear magnetic resonance instrument assembly attached to a central region of the mounting bridge and positioned within the central bore of the vessel, the instrument assembly including a nuclear magnetic resonance coil.

2. The spectrometer of claim 1, wherein the nuclear magnetic resonance coil is a shim coil.

3. The spectrometer of claim 1, wherein the nuclear magnetic resonance coil is a radio-frequency coil.

4. The spectrometer of claim 1, wherein the mounting bridge is attached to the vessel along a peripheral region of the end cover.

5. The spectrometer of claim 4, wherein a distance between an innermost mounting bridge-vessel attachment point and a perimeter of the end cover is less than 10% of a transverse size of the end cover.

6. The spectrometer of claim 4, wherein the mounting bridge is fastened directly to the end cover.

7. The spectrometer of claim 1, wherein the mounting bridge is attached to the vessel along the side wall.

8. The spectrometer of claim 1, wherein the mounting bridge is attached to the vessel along a perimeter of the end cover.

9. The spectrometer of claim 1, wherein the mounting bridge comprises a central aperture co-centered with the central bore of the vessel.

10. The spectrometer of claim 1, wherein the mounting bridge comprises a quasi-rectangular plate extending substantially along a diameter of the end cover.

11. The spectrometer of claim 1, wherein the mounting bridge comprises at least three radial spokes each extending between the central region of the end cover and a perimeter of the end cover.

12. The spectrometer of claim 1, wherein the end cover is formed by a flat plate.

13. The spectrometer of claim 1, wherein the vessel is a cryostat having a vacuum-pressure internal chamber on an internal side of the end cover.

14. A method comprising:
suspending a nuclear magnetic resonance instrument mounting bridge across a central region of an end cover of a nuclear magnetic resonance magnet vessel, the vessel including a longitudinal central bore extending through the end cover; and
attaching a nuclear magnetic resonance instrument assembly to a central region of the mounting bridge to position the nuclear magnetic instrument assembly within the central bore, the instrument assembly including a nuclear magnetic resonance coil.

15. The method of claim 14, wherein the nuclear magnetic resonance coil is a shim coil.

16. The method of claim 14, wherein the nuclear magnetic resonance coil is a radio-frequency coil.

17. The method of claim 14, comprising attaching the mounting bridge to the vessel along a peripheral region of the end cover.

18. The method of claim 14, comprising attaching the mounting bridge to the vessel along a side wall of the vessel.

19. The method of claim 14, comprising attaching the mounting bridge to the vessel along a perimeter of the end cover.

20. The method of claim 14, comprising co-centering a central aperture of the mounting bridge with the central bore of the vessel.

21. The method of claim 14, wherein the end cover is formed by a flat plate.

22. The method of claim 14, wherein the vessel is a cryostat having a vacuum-pressure internal chamber on an internal side of the end cover.
